(19) United States
(12) Patent Application Publication
(10) Pub. No.: US 2024/0321655 A1
(43) Pub. Date: Sep. 26, 2024

(54) SEMICONDUCTOR MODULE

(71) Applicant: FUJI ELECTRIC CO., LTD., Kawasaki-shi (JP)

(72) Inventor: Shuangching CHEN, Matsumoto-city (JP)

(73) Assignee: FUJI ELECTRIC CO., LTD., Kawasaki-shi (JP)

(21) Appl. No.: 18/679,891

(22) Filed: May 31, 2024

Related U.S. Application Data
(63) Continuation of application No. PCT/JP2023/017386, filed on May 9, 2023.

(30) Foreign Application Priority Data
Jun. 1, 2022 (JP) 2022-089501

(51) Int. Cl. H01L 23/14; H01L 23/00; H01L 27/06; H01L 29/861

(52) U.S. Cl. CPC H01L 23/142; H01L 24/46; H01L 27/0629; H01L 29/861; H01L 2224/46

(57) ABSTRACT

A semiconductor module includes an insulated substrate, a conductive pattern, a transistor, a negative power source terminal spaced apart from the transistor in a first direction, and an auxiliary wire coupled to the conductive pattern, in which the transistor includes an emitter electrode, and a gate electrode spaced apart from the emitter electrode in the first direction, a current flows from a specific point over the conductive pattern through the transistor to the negative power source terminal, the emitter electrode includes a first portion and a second portion spaced apart from the first portion in a second direction opposite to the first direction, the auxiliary wire includes a first end closer to the specific point and a second end closer to the transistor, and the second end is closer to the second portion than to the first portion.

### CROSS REFERENCE TO RELATED APPLICATIONS

This Application is a Continuation Application of PCT Application No. PCT/JP2023/017386, filed on May 9, 2023, and is based on, and claims priority from, Japanese Patent Application No. 2022-089501, filed on Jun. 1, 2022, the entire contents of each of which are incorporated herein by reference.

### BACKGROUND

### Field of the Invention

This disclosure relates to semiconductor modules.

### Related Art

There is known a semiconductor module that is used in a power conversion device such as an inverter device. Such a semiconductor module includes a semiconductor element such as an insulated gate bipolar transistor (IGBT), a power metal oxide semiconductor field effect transistor (MOSFET), a freewheeling diode (FWD), etc.

A semiconductor module disclosed in Japanese Patent Application Laid-Open Publication No. 2010-251551 includes an insulated substrate, a plurality of conductive patterns provided over the insulated substrate, and a semiconductor element. The semiconductor element has a lower surface that is a collector electrode. The lower surface is coupled to a conductive pattern of the plurality of conductive patterns via a solder material. The semiconductor element has an upper surface that is provided with an emitter terminal and with a gate terminal that is a control terminal.

A current flowing into a conductive pattern electrically connected to a collector and a current flowing into a conductive pattern electrically connected to an emitter are each greater than a current flowing into a conductive pattern electrically connected to a gate. Japanese Patent Application Laid-Open Publication No. 2010-251551 discloses a technique for coupling a plurality of metallic wires to the conductive pattern electrically connected to the collector such that a large current can readily flow into the conductive pattern electrically connected to the collector. Not only difference in ease of flow of current between a plurality of conductive patterns, but also difference in ease of flow of current between regions in a semiconductor element occurs. Thus, for example, in a configuration in which an upper surface of a semiconductor element is provided with an emitter electrode, the emitter electrode includes a region into which current is easy to flow and a region into which current is difficult to flow. There is a risk that the region into which current is easy to flow tends to generate heat more readily than the region into which current is difficult to flow.

In a configuration in which the upper surface of the semiconductor element is further provided with a control electrode such as a gate terminal, there is a risk that an area of one portion of the emitter electrode adjacent to the control electrode is smaller than an area of each of the other portions of the emitter electrode. In addition, in a configuration in which the emitter electrode is, for example, coupled to various wires, there is a risk that the number of wires coupled to the portion of the emitter electrode adjacent to the control electrode is less than the number of wires coupled to each of the other portions of the emitter electrode. Thus, in a configuration in which the portion of the emitter electrode adjacent to the control electrode is included in the region into which current is easy to flow, various wires tend to generate heat further. This may cause damage, etc.

### SUMMARY

There is need to reduce difference in ease of flow of current between regions in a semiconductor element.

In one aspect, a semiconductor module includes: an insulated substrate; a conductive pattern over the insulated substrate; a transistor over the conductive pattern; a connection terminal over the insulated substrate, the connection terminal being spaced apart from the transistor in a first direction; and an auxiliary wire coupled to the conductive pattern, in which the transistor includes: a first main electrode provided on a first surface facing the conductive pattern; a second main electrode provided on a second surface opposite to the first surface; and a control electrode over the second surface, the control electrode being spaced apart from the second main electrode in the first direction, in which a current flows from a specific point on the conductive pattern through the transistor to the connection terminal, the specific point being spaced apart from the transistor in the first direction, in which the second main electrode includes a first portion provided in a first direction and a second portion that is spaced apart from the first portion in a second direction opposite to the first direction, in which the auxiliary wire includes: a first end close to the specific point; and a second end close to the transistor, and in which the second end is closer to the second portion than to the first portion.

In another aspect, a semiconductor module includes: an insulated substrate; a conductive pattern over the insulated substrate; a transistor over the conductive pattern; and a connection terminal over the insulated substrate, the connection terminal being spaced apart from the transistor in a first direction; in which the transistor includes: a first main electrode provided on a first surface facing the conductive pattern; a second main electrode provided on a second surface opposite to the first surface; and a control electrode over the second surface, the control electrode being spaced apart from the second main electrode in the first direction, in which a current flows from a specific point on the conductive pattern through the transistor to the connection terminal, the specific point being spaced apart from the transistor in the first direction, in which the second main electrode includes a first portion and a second portion that is spaced apart from the first portion in a second direction opposite to the first direction, and in which the conductive pattern is provided with a slit between the specific point and the first portion.

### BRIEF DESCRIPTION OF THE DRAWINGS

FIG. 1 is a plan view of a semiconductor module according to a first embodiment.

FIG. 2 is a diagram showing a one-phase circuit included in a three-level power conversion circuit.

FIG. 3 is a plan view of a semiconductor unit shown in FIG. 2.

FIG. 4 is a cross section taken along line A1-A1 shown in FIG. 3.

FIG. 5 is an explanatory diagram showing flow of current through the semiconductor unit shown in FIG. 4.

FIG. 6 is an explanatory diagram showing current paths from a specific point to a transistor.

FIG. 7 is a plan view of the semiconductor unit according to a second embodiment.

FIG. 8 is a plan view of the semiconductor unit according to a third embodiment.

### DESCRIPTION OF EMBODIMENTS

Embodiments according to this disclosure will be described with reference to the accompanying drawings. In the drawings, dimensions and scales of elements may differ from those of actual products, and some elements may be shown schematically to facilitate understanding. The scope of this disclosure is not limited to the embodiments described below unless the following explanation includes a description that specifically limits the scope of this disclosure.

In the following description, for convenience, an X-axis, a Y-axis, and a Z-axis are appropriately used that are perpendicular to one another. In the following, a direction along the X-axis is a direction X1, whereas a direction opposite to the direction X1 is a direction X2. A direction along the Y-axis is a direction Y1, whereas a direction opposite to the direction Y1 is a direction Y2. A direction along the Z-axis is a direction Z1, whereas a direction opposite to the direction Z1 is a direction Z2. A plane along the X-axis and the Y-axis is referred to as an X-Y plane. In the following, a view in a normal direction of the X-Y plane is referred to as a “plan view.” The direction Z1 is referred to as an “upward direction,” whereas the direction Z2 is referred to as a “downward direction.” The direction X1 is a “first direction,” whereas the direction X2 is a “second direction.” In addition, “element β over an element α” means that the element β is disposed over the element α. Thus, “element β over an element α” includes not only a case in which the element β is in directly contact with the element α, but also a case in which the element α and the element β are spaced apart from each other. In addition, “electrically connection” between an element α and an element β includes not only a configuration in which the element α and the element β are electrically connected to each other by the element α and the element β being directly coupled to each other, but also a configuration in which the element α and the element β are electrically connected to each other via one or more other conductors.

### 1. Semiconductor Module 1

### 1-1. Outline of Semiconductor Module 1

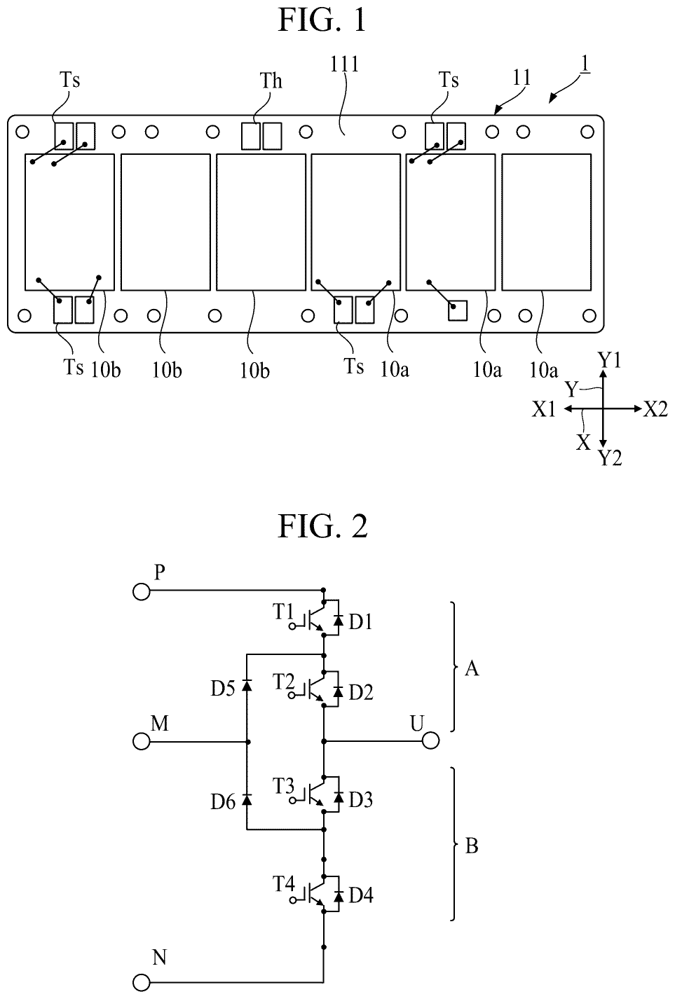

FIG. 1 is a plan view of a semiconductor module 1 according to this embodiment. The semiconductor module 1 shown in FIG. 1 is used, for example, as a power conversion device such as a power module. The semiconductor module 1 includes a heat radiating board 11, a plurality of semiconductor units 10a, and a plurality of semiconductor units 10b.

The heat radiating board 11 is a plate-shaped board that functions as a base for the plurality of semiconductor units 10a and for the plurality of semiconductor units 10b. The heat radiating board 11 is made of a material that has excellent thermal conductivity. The material of the heat radiating board 11 is, for example, a metallic material such as a copper material, an aluminum material, etc., or an alloy, etc. An upper surface 111 of the heat radiating board 11 may be plated with a metallic material such as a nickel or with an alloy, so as to improve corrosion resistance.

The heat radiating board 11 is provided with a thermistor Th and a plurality of external terminals Ts for inputting current to, and for receiving current from, the plurality of semiconductor units 10a and the plurality of semiconductor units 10b. The upper surface 111 of the heat radiating board 11 is parallel to the X-Y plane. A direction of thickness of the heat radiating board 11 is parallel to the normal direction of the X-Y plane. In an example shown in FIG. 1, in plan view, the heat radiating board 11 has a shape of a rectangle having a longitudinal direction that is the X1 direction; however, this is merely an example, and it may be changed to a desired shape as appropriate.

The upper surface 111 of the heat radiating board 11 is provided with the plurality of semiconductor units 10a and the plurality of semiconductor units 10b. In the example shown in FIG. 1, the plurality of semiconductor units 10a and the plurality of semiconductor units 10b are aligned with each other in the direction X1. The number of semiconductor units 10a shown in FIG. 1 and the number of semiconductor units 10b shown in FIG. 1 are each an example, and a required number of semiconductor units 10a and a required number of semiconductor units 10b may be disposed.

The plurality of semiconductor units 10a and the plurality of semiconductor units 10b each include, for example, a switching element, a diode, etc. Examples of the switching element include an insulated gate bipolar transistor (IGBT), a power metal oxide semiconductor field effect transistor (MOSFET), etc. Examples of the diode include a freewheeling diode (FWD), etc.

A semiconductor unit 10a and a semiconductor unit 10b can constitute a one-phase circuit included in a three-level power conversion circuit. A configuration, in which the plurality of semiconductor units 10a and the plurality of semiconductor units 10b are provided, can handle greater current. In the semiconductor module 1 according to this embodiment, a one-phase circuit included in a three-level power conversion circuit is constituted of the plurality of semiconductor units 10a and the plurality of semiconductor units 10b.

### 1-2. Three-Level Power Conversion Circuit

FIG. 2 is a diagram showing the one-phase circuit included in the three-level power conversion circuit. As shown in FIG. 2, the one-phase circuit is constituted of four transistors T1, T2, T3, and T4, and six diodes D1, D2, D3, D4, D5, and D6. In this embodiment, each of the transistors T1 to T4 is an IGBT. Each of the diodes D1 to D6 is an FWD.

The transistors T1 to T4 and the diodes D1 to D4 constitute an inverter. The transistors T1, T2, T3, and T4 are connected in series to one another. The transistors T1 and T2 constitute an upper arm A of the inverter, whereas the transistors T3 and T4 constitute a lower arm B of the inverter. Each of the semiconductor units 10a shown in FIG. 1 includes the upper arm A of the inverter. Each of the semiconductor units 10b shown in FIG. 1 includes the lower arm B of the inverter.

The diode D1 is connected in reverse parallel to the transistor T1. The diode D2 is connected in reverse parallel to the transistor T2. The diode D3 is connected in reverse parallel to the transistor T3. The diode D4 is connected in reverse parallel to the transistor T4.

Each of the transistors T1, T2, T3, and T4 has a collector, an emitter, and a gate. The collector of the transistor T1 is connected to a positive power source terminal P that is connected to a positive side of a direct-current power supply. The emitter of the transistor T4 is connected to a negative power source terminal N that is connected to a negative side of the direct-current power supply. The negative power source terminal N is a “connection terminal.” A connection point between the emitter of the transistor T2 and the collector of the transistor T3 is connected to an alternating-current output terminal U. A connection point between an anode of the diode D5 and a cathode of the diode D6 is connected to an intermediate terminal M.

According to the semiconductor module 1 including the three-level power conversion circuit, a mounted area of the semiconductor module 1 is small, and it is possible to reduce the size of the module having excellent conversion efficiency. In addition, the semiconductor module is in one package; as a result, it is possible to reduce internal inductance thereof.

### 1-3. Each Semiconductor Unit 10b

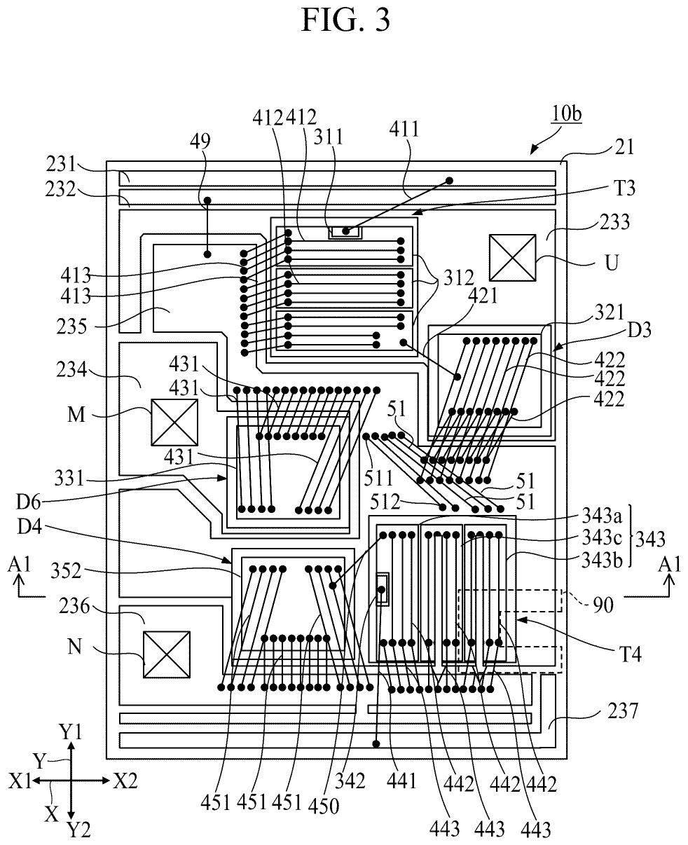

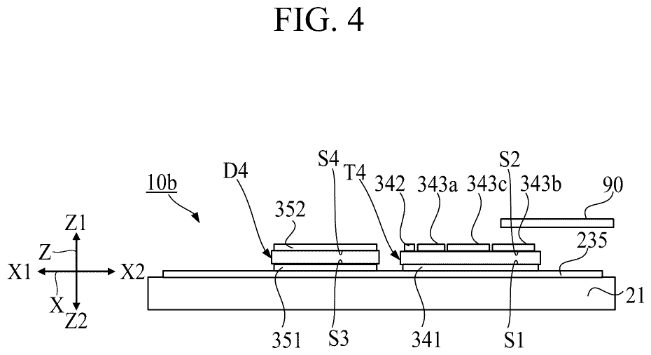

FIG. 3 is a plan view of each of the plurality of semiconductor units 10b shown in FIG. 1. FIG. 4 is a cross section taken along line A1-A1 shown in FIG. 3. As shown in FIG. 3, each of the plurality of semiconductor units 10b includes an insulated substrate 21, a plurality of conductive patterns 231, 232, 233, 234, 235, 236, and 237, the two transistors T3 and T4, the three diodes D3, D4 and D6, the output terminal U, the intermediate terminal M, the negative power source terminal N, and a plurality of auxiliary wires 51.

In an example shown in the drawing, a shape of the insulated substrate 21 is rectangular in plan view. The insulated substrate 21 has insulation. Examples of a material of the insulated substrate 21 include a ceramic material such as aluminum oxide and a resin material such as an epoxy resin material. Although not shown, a lower surface of the insulated substrate 21 is provided with a metallic plate that is to be bonded to the heat radiating board 11 shown in FIG. 1.

An upper surface of the insulated substrate 21 is provided with each of the plurality of conductive patterns 231 to 237. Each of the plurality of conductive patterns 231 to 237 is electrically conductive and is made of, for example, a metallic material such as a copper material, an aluminum material, etc., or an alloy, etc. The plurality of conductive patterns 231 to 237 are electrically spaced apart from one another. A thickness of each of the plurality of conductive patterns 231 to 237 is not particularly limited, and it may be 0.1 millimeters or greater and 2.0 millimeters or less. The plurality of conductive patterns 231 to 237 have the same thickness.

Over the conductive pattern 233 shown in FIG. 3, the output terminal U, the transistor T3, and the diode D3 are provided. The output terminal U, the transistor T3, and the diode D3 are electrically connected to the conductive pattern 233. The conductive pattern 235 is electrically connected to the conductive pattern 232 via a wire 49. The output terminal U is spaced apart from the transistor T3 in the direction X2.

The transistor T3 includes a collector electrode (not shown), a gate electrode 311, and an emitter electrode 312. The collector electrode is an electrode provided on a lower surface of a semiconductor layer, and the collector electrode is bonded to the conductive pattern 233 via, for example, a solder material or a conductive paste. The gate electrode 311 and the emitter electrode 312 are each an electrode provided on an upper surface of the semiconductor layer. The gate electrode 311 is spaced apart from the emitter electrode 312 in the direction Y1. The gate electrode 311 is electrically connected to the conductive pattern 231 via a wire 411. In the example shown in the drawing, the emitter electrode 312 is divided into three portions that are aligned with one another in the direction Y1. Over an upper surface of the emitter electrode 312, a plurality of wires 412 is provided. Each of the plurality of wires 412 extends in the direction X1. Both ends of each of the plurality of wires 412 are coupled to the emitter electrode 312. A current, which has flowed into the emitter electrode 312, partly flows through each of the plurality of wires 412. The emitter electrode 312 is electrically connected to the conductive pattern 235 via a 20) plurality of wires 413.

The diode D3 includes a cathode electrode (not shown) and an anode electrode 321. The cathode electrode is an electrode provided on a lower surface of a semiconductor layer, and the cathode electrode is bonded to the conductive pattern 233 via, for example, a solder material or a conductive paste. The anode electrode 321 is an electrode provided on an upper surface of the semiconductor layer. The anode electrode 321 is electrically connected to the emitter electrode 312 via a wire 421. The anode electrode 321 is electrically connected to the conductive pattern 235 via a plurality of wires 422 including wires 422 that are different in length from each other.

Over the conductive pattern 234, the intermediate terminal M and the diode D6 are provided. The intermediate terminal M and the diode D6 are electrically connected to the conductive pattern 234. The intermediate terminal M is spaced apart from the diode D6 in the direction X1.

The diode D6 includes a cathode electrode (not shown) and an anode electrode 331. The cathode electrode is an electrode provided on a lower surface of a semiconductor layer, and the cathode electrode is bonded to the conductive pattern 234 via, for example, a solder material or a conductive paste. The anode electrode 331 is an electrode provided on an upper surface of the semiconductor layer. The anode electrode 331 is electrically connected to the conductive pattern 235 via a plurality of wires 431 including wires 431 that are different in length from each other.

Over the conductive pattern 235, the transistor T4 and the diode D4 are provided. The transistor T4 and the diode D4 are electrically connected to the conductive pattern 235.

As shown in FIG. 4, the transistor T4 includes a collector electrode 341, a gate electrode 342, and an emitter electrode 343. The collector electrode 341 corresponds to a “first main electrode.” The collector electrode 341 is provided on a first surface S1 that faces the conductive pattern 235. The collector electrode 341 is bonded to the conductive pattern 235 via, for example, a solder material or a conductive paste. The gate electrode 342 corresponds to a “control electrode,” whereas the emitter electrode 343 corresponds to a “second main electrode.” The gate electrode 342 and the emitter electrode 343 are each provided on a second surface S2 opposite to the first surface S1.

As shown in FIG. 3, the gate electrode 342 is spaced apart from the emitter electrode 343 in the direction X1. In other words, a position of the gate electrode 342 on the X-axis is apart from a position of the emitter electrode 343 on the X-axis in the direction X1. The gate electrode 342 is electrically connected to the conductive pattern 237 via a wire 441.

In the example shown in the drawing, the emitter electrode 343 is divided into three portions that include a first portion 343a, a second portion 343b, and a third portion 343c. The first portion 343a, the third portion 343c, and the second portion 343b are aligned with one another, in this order, in the direction X2. Thus, in plan view, the third portion 343c is interposed between the first portion 343a and the second portion 343b. The second portion 343b and the third portion 343c are spaced apart from the first portion 343a in the direction X2 that is the “second direction.” In other words, a position of the second portion 343b on the X-axis and a position of the third portion 343c on the X-axis are apart from a position of the first portion 343a on the X-axis in the direction X2.

The first portion 343a is provided to be close to the gate electrode 342. The first portion 343a, the second portion 343b, and the third portion 343c have the same width and the same total length. Width means length in the direction X1. Total length means length in the direction Y1. A long side of the first portion 343a is provided with a recess, and the gate electrode 342 is provided within the recess. Thus, an area of the first portion 343a is smaller than an area of the second portion 343b by an area of the gate electrode 342, and the area of the first portion 343a is smaller than an area of the third portion 343c by the area of the gate electrode 342. The area of the second portion 343b is approximately equal to the area of the third portion 343c.

Over an upper surface of the emitter electrode 343, a plurality of wires 442 is provided. Each of the plurality of wires 442 extends in the direction Y1. Both ends of each of the plurality of wires 442 are coupled to the emitter electrode 343. A current, which has flowed into the emitter electrode 343, partly flows through each of the plurality of wires 442. Since the plurality of wires 442 is provided, compared to a configuration in which the plurality of wires 442 is not provided, a current can flow through an entire area of the emitter electrode 343 in a well-balanced manner.

As described above, the area of the first portion 343a is smaller than the area of the second portion 343b, and the area of the first portion 343a is smaller than the area of the third portion 343c. Thus, the number of wires 442 coupled to the first portion 343a is less than the number of wires 442 coupled to the second portion 343b. Similarly, the number of wires 442 coupled to the first portion 343a is less than the number of wires 442 coupled to the third portion 343c. In the example shown in FIG. 3, three wires 442 are coupled to the first portion 343a, four wires 442 are coupled to the second portion 343b, and four wires 442 are coupled to the third portion 343c.

The emitter electrode 343 is electrically connected to the conductive pattern 236 via a plurality of wires 443.

As shown by a dashed line in FIG. 3 and as shown in FIG. 4, over the second portion 343b of the emitter electrode 343, an external connection terminal 90 is provided. Although not shown in detail, the external connection terminal 90 is coupled to, for example, a negative power source terminal N or an intermediate terminal M included in an adjacent semiconductor unit 10b, and the external connection terminal 90 is used for connection to an external terminal Ts included in the adjacent semiconductor unit 10b. Since the external connection terminal 90 is provided over the second portion 343b, it is possible to cause two adjacent semiconductor units 10b to be close to each other. Thus, it is possible to reduce the size of the semiconductor module 1.

As shown in FIG. 3, over the conductive pattern 235, the plurality of auxiliary wires 51 is provided. Each of the plurality of auxiliary wires 51 is coupled to the conductive pattern 235. Each of the plurality of auxiliary wires 51 is linear in plan view, and each of the plurality of auxiliary wires 51 includes a first end 511 and a second end 512 that are coupled to the conductive pattern 235. The first end 511 is spaced apart from the second end 512 in the direction Y1. In other words, a position of the first end 511 on the Y-axis is apart from a position of the second end 512 on the Y-axis in the direction Y1. A current, which has flowed into the conductive pattern 235, partly flows through the plurality of auxiliary wires 51. Since the plurality of auxiliary wires 51 is provided, it is possible to reduce difference in ease of flow of current between regions in the conductive pattern 235. In the example shown in FIG. 3, the plurality of auxiliary wires 51 comprises wires; however, the plurality of auxiliary wires 51 may comprise a ribbon cable or a lead frame, etc.

As shown in FIG. 3, the diode D4 over the insulated substrate 21 is spaced apart from the transistor T4 in the direction X1 that is the “first direction.” In other words, a position of the diode D4 on the X-axis is apart from a position of the transistor T4 on the X-axis in the direction X1.

As shown in FIG. 4, the diode D4 includes a cathode electrode 351 and an anode electrode 352. The cathode electrode 351 is provided on a third surface S3 that faces the conductive pattern 235. The cathode electrode 351 is bonded to the conductive pattern 235 via, for example, a solder material or a conductive paste. The anode electrode 352 is provided on a fourth surface S4 opposite to the third surface S3.

As shown in FIG. 3, the anode electrode 352 is electrically connected to the emitter electrode 343 via a wire 450 that is a “relay wire.” Thus, the wire 450 electrically connects the diode D4 and the transistor T4 to each other. One end of the wire 450 is coupled to the first portion 343a of the emitter electrode 343, whereas the other end of the wire 450 is coupled to the anode electrode 352. Since the wire 450 is provided, compared to a configuration in which the wire 450 is not provided, it is possible to substantially prevent parasitic oscillation, thereby reducing noise.

The anode electrode 352 is electrically connected to the conductive pattern 236 via a plurality of wires 451.

Over the conductive pattern 236, the negative power source terminal N is provided. The negative power source terminal N is electrically connected to the conductive pattern 236. The negative power source terminal N is spaced apart from the transistor T4 in the direction X1 that is the “first direction.” In other words, a position of the negative power source terminal N on the X-axis is apart from the position of the transistor T4 on the X-axis in the direction X1.

The wire 49, 411, 421, 441, and 450, and the plurality of wires 412, 413, 422, 431, 442, 443, and 451 described above may each be replaced with a ribbon cable or lead frame.

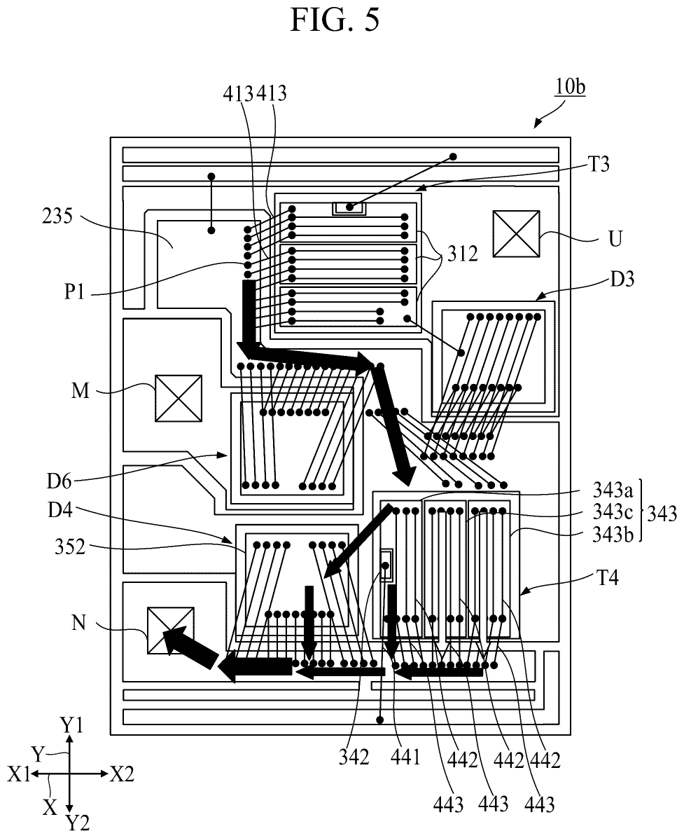

FIG. 5 is an explanatory diagram showing flow of current through the semiconductor unit 10b shown in FIG. 4. In the semiconductor unit 10b, as indicated by a plurality of arrows shown in FIG. 5, a current flows. The current flows from the plurality of wires 413, with which the transistor T3 is provided, through the transistor T4 to the negative power source terminal N that is the “connection terminal.”

For example, a junction of a wire 413 of the plurality of wires 413 and the conductive pattern 235 is referred to as a specific point P1. The specific point P1 is spaced apart from the transistor T4 in the direction X1 that is the “first direction.” In other words, a position of the specific point P1 on the X-axis is apart from the position of the transistor T4 on the X-axis in the direction X1. In the conductive pattern 235, the current flows from the specific point P1 to the transistor T4, and then the current flows to the negative power source terminal N.

The current flowing from the specific point P1 to the transistor T4 flows through a portion of the conductive pattern 235 having smaller inductance than the other portion of the conductive pattern 235. Thus, the current flows from the specific point P1 to the transistor T4 by flowing through a short path in the conductive pattern 235. Consequently, difference in ease of flow of current between regions in the conductive pattern 235 occurs; as a result, difference in ease of flow of current between regions in the transistor T4 occurs. To reduce these differences based on regions, the plurality of auxiliary wires 51 is provided.

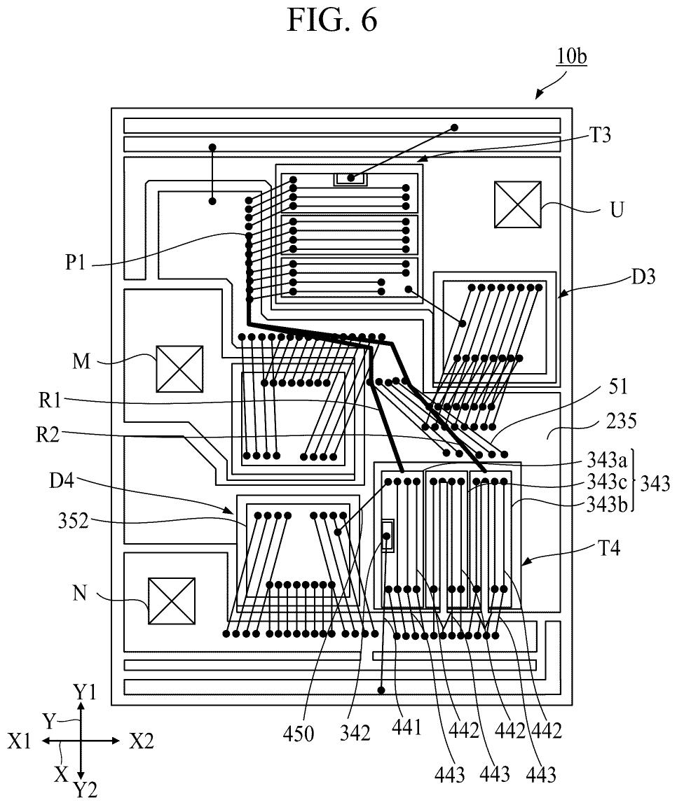

FIG. 6 is an explanatory diagram showing current paths from the specific point P1 to the transistor T4. As described above, the specific point P1 is spaced apart from the transistor T4 in the direction X1. The first portion 343a of the transistor T4 is spaced apart from the second portion 343b in the direction X1. Thus, the first portion 343a over the conductive pattern 235 is closer to the specific point P1 than the second portion 343b. As a result, a first shortest path R1 is shorter than a second shortest path R2, the first shortest path R1 being a path on the conductive pattern 235 from the specific point P1 to the first portion 343a, the second shortest path R2 being a path on the conductive pattern 235 from the specific point P1 to the second portion 343b.

The first shortest path R1 is shorter than the second shortest path R2. Thus, in a configuration in which the plurality of auxiliary wires 51 is not provided, an inductance of the first shortest path R1 is less than an inductance of the second shortest path R2. Consequently, the current is easy to flow into the first shortest path R1 having a small inductance, whereas the current is difficult to flow into the second shortest path R2 having a large inductance. As a result, in the transistor T4, an amount of current flowing into the first portion 343a is greater than an amount of current flowing into the second portion 343b. In addition, the negative power source terminal N that is the “connection terminal” is spaced apart from the transistor T4 in the direction X1. Thus, compared to a configuration in which the negative power source terminal N is spaced apart from the transistor T4 in the direction X2, an amount of current flowing into the first portion 343a tends to be greater than an amount of current flowing into the second portion 343b.

To reduce the inductance of the second shortest path R2 so as to reduce an amount of current flowing into the first portion 343a, the plurality of auxiliary wires 51 is provided. Specifically, each of the plurality of auxiliary wires 51 includes the first end 511 and the second end 512, the first end 511 being close to the specific point P1, the second end 512 being close to the transistor T4. The second end 512 is closer to the second portion 343b than to the first portion 343a.

Since each of the plurality of auxiliary wires 51 is provided such that the second end 512 is closer to the second portion 343b than to the first portion 343a, the plurality of auxiliary wires 51 is provided so as to be along the second shortest path R2. Thus, a current for the second shortest path R2 partly flows into the plurality of auxiliary wires 51; as a result, it is possible to reduce the inductance of the second shortest path R2. Consequently, it is possible to reduce the amount of current flowing into the first portion 343a. Thus, it is possible to reduce difference in ease of flow of current between the first portion 343a and the second portion 343b. As a result, it is possible to reduce difference in ease of flow of current between regions in the transistor T4.

Since it is possible to reduce the amount of current flowing into the first portion 343a, it is possible to reduce a risk of damage to the plurality of wires 422 coupled to the first portion 343a due to heat generated by the plurality of wires 422. Since the plurality of auxiliary wires 51 is provided, compared to a configuration in which a single auxiliary wire 51 is provided, it is possible to effectively reduce difference in ease of flow of current between regions in the transistor T4.

In particular, in the transistor T4, the gate electrode 342 is spaced apart from the emitter electrode 343 in the direction X1. Thus, the first portion 343a is closer to the gate electrode 342 than the second portion 343b, thereby increasing limitations due to the gate electrode 342. Specifically, as described above, the area of the first portion 343a is smaller than the area of the second portion 343b, and the number of wires 442 coupled to the first portion 343a is less than the number of wires 442 coupled to the second portion 343b. Thus, a large current tends to flow into each of the wires 442 coupled to the first portion 343a compared to each of the wires 442 coupled to the second portion 343b.

In a configuration in which the gate electrode 342 is closer to the first portion 343a than to the second portion 343b in addition to the first shortest path R1 being shorter than the second shortest path R2, a large current particularly tends to flow through the first portion 343a. Thus, an advantage can be particularly obtained in that the plurality of auxiliary wires 51 reduces an amount of current flowing into the first portion 343a. As a result, it is possible to substantially prevent damage to the wires 443 connected to the first portion 343a.

As described above, the first portion 342a is coupled to one end of the wire 450 electrically connecting the transistor T4 and the diode D6 to each other. Reduction in area of the first portion 343a due to the gate electrode 342 being provided in a vicinity of the first portion 343a restricts the number of wires 450. Thus, a large current tends to flow through the wire 450. As described above, since the plurality of auxiliary wires 51 reduces an amount of current flowing into the first portion 343a, it is possible to reduce an amount of current flowing into the wire 450. Thus, it is possible to reduce noise by the wire 450 being provided, and it is possible to reduce risk of damage to the wire 450. As a result, it is possible to provide a semiconductor module 1 having high reliability.

As shown in FIG. 4, over the second portion 343b of the emitter electrode 343, the external connection terminal 90 is provided. For example, a case may be conceived in which, if the gate electrode 342 is spaced apart from the second portion 343b in the direction X2, the gate electrode 342 is provided in a region through which the current is difficult to flow; thus, it is possible to substantially prevent damage to the wires 442 coupled to the first portion 343a described above. However, in this case, the external connection terminal 90 and the gate wire interfere with each other to increase current; thus, damage tends to occur. Thus, according to the configuration in which the plurality of auxiliary wires 51 described above is provided in addition to the external connection terminal 90 being provided over the second portion 343b, it is possible to provide the semiconductor unit 10b having high reliability caused by a reduced risk of damage to the wires 442.

### 2. Second Embodiment

In the following, a second embodiment according to this disclosure will be described. In the description of the following embodiment, elements having the same operations and the same functions as in the first embodiment described above are denoted by the same reference numerals used for like elements in the description of the first embodiment, and detailed description thereof is omitted, as appropriate.

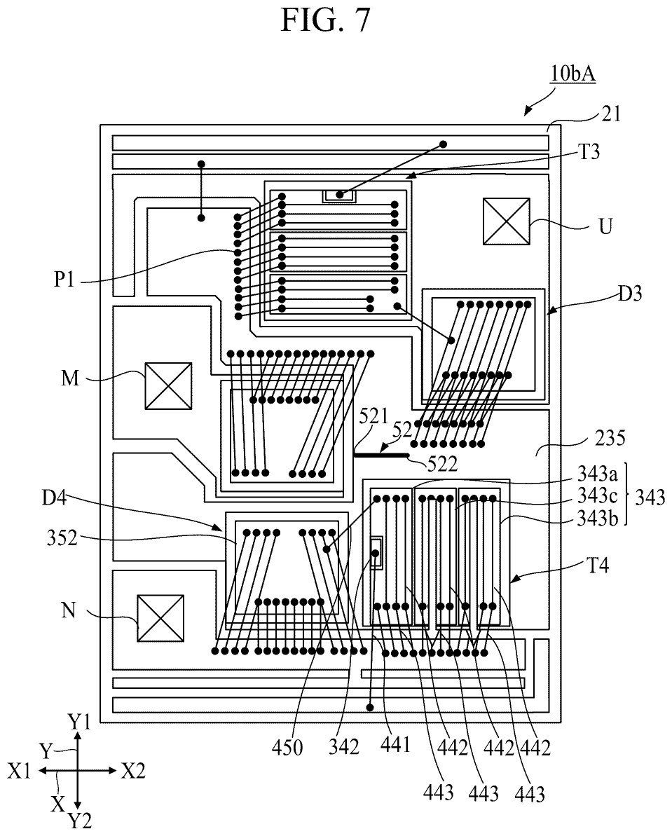

FIG. 7 is a plan view of a semiconductor unit 10bA according to the second embodiment. As shown in FIG. 7, this embodiment has the same configuration as that of the first embodiment, except that the plurality of auxiliary wires 51 is omitted, and except that the conductive pattern 235 is provided with a slit 52.

As shown in FIG. 7, the conductive pattern 235 is provided with the slit 52. The slit 52 penetrates the conductive pattern 235 in a direction of thickness of the conductive pattern 235. The slit 52 includes one end 251 and the other end 252, and the slit 52 has a shape of a straight line parallel to the X-axis in plan view. The slit 52 is provided between the specific point P1 on the conductive pattern 235 and the first portion 343a.

As shown in the FIG. 6 described above, when the slit 52 is not provided, the first shortest path R1 is shorter than the second shortest path R2. Thus, when the slit 52 is not provided, the inductance of the second shortest path R2 is greater than the inductance of the first shortest path R1. As a result, the current is more difficult to flow into the second portion 343b than into the first portion 343a.

By the slit 52 being provided, it is possible to increase a length of a current path from the specific point P1 to the first portion 343a. Consequently, since an inductance of the path from the specific point P1 to the first portion 343a is increased, it is possible to reduce an amount of current flowing into the first portion 343a. Thus, it is possible to reduce difference in ease of flow of current between the first portion 343a and the second portion 343b. As a result, it is possible to substantially prevent difference in ease of flow of current between regions in the transistor T4.

In addition, by the slit 52 being provided, it is possible to reduce an amount of current flowing into the first portion 343a. Thus, as in the first embodiment, it is possible to reduce a risk of damage to the wires 442 coupled to the first portion 343a due to heat generated by the wires 442.

In the configuration in which the gate electrode 342 is closer to the first portion 343a than to the second portion 343b as in the first embodiment, an advantage can be particularly obtained in that the slit 52 reduces an amount of current flowing into the first portion 343a.

The slit 52 is provided across the first shortest path R1 that is in a state in which the slit 52 is not provided. Thus, it is possible to reliably increase a length of a current path from the specific point P1 to the first portion 343a. As a result, it is possible to reliably reduce an amount of current flowing into the first portion 343a.

In an example shown in the drawing, a position of the slit 52 on the X-axis is the same as the position of the first portion 343a on the X-axis. Thus, it is possible to reliably increase the length of the current path from the specific point P1 to the first portion 343a. In addition, the position of the slit 52 on the X-axis is separated from the position of the second portion 343b on the X-axis in the direction X1. Thus, it is possible to increase the length of the current path from the specific point P1 to the first portion 343a without increasing the length of the current path from the specific point P1 to the second portion 343b.

In the example shown in the drawing, one end 521 of the slit 52 is provided on an end side of the conductive pattern 235 in the direction X1, whereas the other end 522 of the slit 52 is provided on a boundary between the first portion 343a and the third portion 343c. However, the other end 522 of the slit 52 may be apart from the boundary in the direction X1, or may be at the position of the third portion 343c on the X-axis.

According to the second embodiment described above, it is possible to substantially prevent difference in ease of flow of current between regions in the transistor T4.

### 3. Third Embodiment

In the following, a third embodiment according to this disclosure will be described. In the description of the following embodiment, elements having the same operations and the same functions as in the first and second embodiments described above are denoted by the same reference numerals used for like elements in the description of the first and second embodiments, and detailed description thereof is omitted, as appropriate.

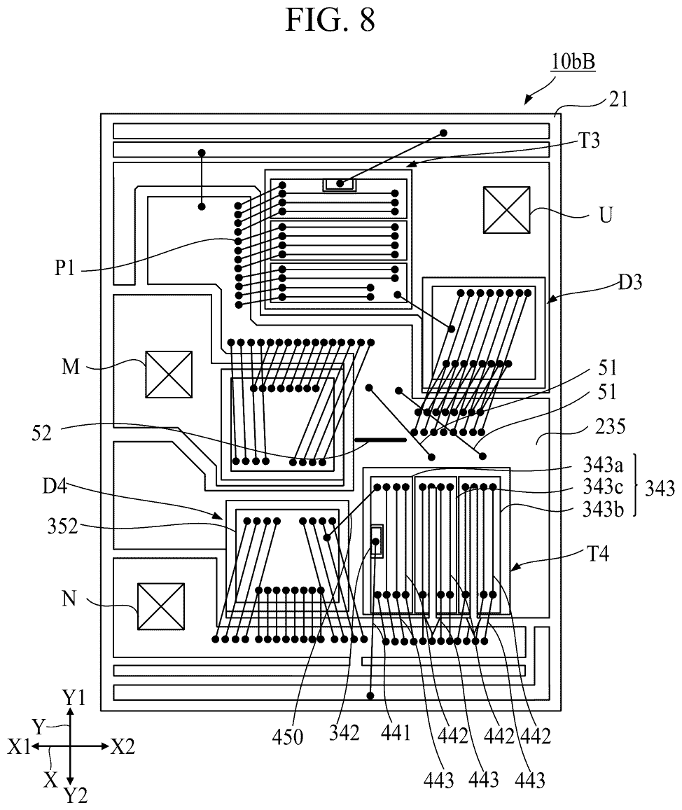

FIG. 8 is a plan view of a semiconductor unit 10bB according to the third embodiment. This embodiment is a combination of the first embodiment and the second embodiment. Specifically, as shown in FIG. 8, this embodiment has the same configuration as that of the first embodiment, except that the number of auxiliary wires 51 is less than that shown in FIG. 3, and except that the slit 52 is provided. This embodiment has the same configuration as that of the second embodiment, except that a plurality of auxiliary wires 51 is provided.

As shown in FIG. 8, the conductive pattern 235 is provided with the plurality of auxiliary wires 51 as in the first embodiment. Thus, it is possible to obtain the same effects as those obtained by the first embodiment. For example, by the plurality of auxiliary wires 51 being provided, it is possible to reduce the inductance of the second shortest path R2. The conductive pattern 235 is provided with the same slit 52 as that in the second embodiment. By the slit 52 being provided, it is possible to obtain the same effects as those obtained by the second embodiment. For example, it is possible to increase the inductance of the path from the specific point P1 to the first portion 343a. Thus, by the plurality of auxiliary wires 51 and the slit 52 being provided, it is possible to substantially prevent difference in ease of flow of current between regions in the transistor T4.

Since the slit 52 is provided, if the number of auxiliary wires 51 is less than the number of auxiliary wires 51 in the first embodiment, it is possible to substantially prevent difference in ease of flow of current between regions in the transistor T4.

According to the third embodiment described above, it is possible to substantially prevent difference in ease of flow of current between regions in the transistor T4. According to the third embodiment, since the auxiliary wires 51 and the slit 52 are provided, it is possible to obtain both the effects due to the auxiliary wires 51 being provided and the effects due to the slit 52 being provided.

### 4. Modifications

Each of the embodiments described above may be variously modified as described below, for example. Modifications may be appropriately combined with one another.

In the foregoing description, each of the transistors T1 and T4 is an IGBT, but it may be a MOSFET, for example. When each of the transistors T1 and T4 is a MOSFET, each of the transistors T1 and T4 includes a drain electrode instead of the collector electrode and includes a source electrode instead of the emitter electrode. Thus, examples of the “first main electrode” include the collector electrode and the drain electrode, and examples of the “second main electrode” include the emitter electrode and the source electrode.

In the foregoing description, although each auxiliary wire 51 is linear in plan view, but an “auxiliary wire” may be bent in plan view. In the foregoing description, although only both ends of the auxiliary wire 51 are connected to the conductive pattern 235, a plurality of portions between both ends of the auxiliary wire 51 may be coupled by stitch bonding to the conductive pattern 235. In the foregoing description, the slit 52 is linear in plan view, but a “slit” may be bent in plan view. Furthermore, the “slit” may be inclined relative to the X-axis and the Y-axis.

Although this disclosure is described based on the embodiments shown in the drawings, this disclosure is not limited thereto. Each of components of this disclosure may be replaced with a freely selected component having the same functions as those of the embodiments described above, and may include a freely selected component.

### DESCRIPTION OF REFERENCE SIGNS

1 . . . semiconductor module, 10a . . . semiconductor unit, 10b . . . semiconductor unit, 10bA . . . semiconductor unit, 10bB . . . semiconductor unit, 11 . . . heat radiating board, 21 . . . insulated substrate, 49 . . . wire, 51 . . . auxiliary wire, 52 . . . slit, 90 . . . external connection terminal, 111 . . . upper surface, 231 . . . conductive pattern, 232 . . . conductive pattern, 233 . . . conductive pattern, 234 . . . conductive pattern, 235 . . . conductive pattern, 236 . . . conductive pattern, 237 . . . conductive pattern, 311 . . . gate electrode, 312 . . . emitter electrode, 321 . . . anode electrode, 331 . . . anode electrode, 341 . . . collector electrode, 342 . . . gate electrode, 343 . . . emitter electrode, 343a . . . first portion, 343b . . . second portion, 343c . . . third portion, 351 . . . cathode electrode, 352 . . . anode electrode, 411 . . . wire, 412 . . . wire, 413 . . . wire, 421 . . . wire, 422 . . . wire, 431 . . . wire, 441 . . . wire, 442 . . . wire, 443 . . . wire, 450 . . . relay wire, 451 . . . wire, 511 . . . first end, 512 . . . second end, 521 . . . one end, 522 . . . other end, A . . . upper arm, B . . . lower arm, D1 . . . diode, D2 . . . diode, D3 . . . diode, D4 . . . diode, D5 . . . diode, D6 . . . diode, M . . . intermediate terminal, N . . . negative power source terminal, P . . . positive power source terminal, P1 . . . specific point, R1 . . . first shortest path, R2 . . . second shortest path, S1 . . . first surface, S2 . . . second surface, S3 . . . third surface, S4 . . . fourth surface, T1 . . . transistor, T2 . . . transistor, T3 . . . transistor, T4 . . . transistor, Ts . . . external terminal, U . . . output terminal.

What is claimed is:

1. A semiconductor module comprising:
an insulated substrate;
a conductive pattern over the insulated substrate;
a transistor over the conductive pattern;
a connection terminal over the insulated substrate, the connection terminal being spaced apart from the transistor in a first direction; and
an auxiliary wire coupled to the conductive pattern,
wherein the transistor includes:
a first main electrode provided on a first surface facing the conductive pattern;
a second main electrode provided on a second surface opposite to the first surface; and
a control electrode over the second surface, the control electrode being spaced apart from the second main electrode in the first direction,
wherein a current flows from a specific point on the conductive pattern through the transistor to the connection terminal, the specific point being spaced apart from the transistor in the first direction,
wherein the second main electrode includes a first portion and a second portion that is spaced apart from the first portion in a second direction opposite to the first direction,
wherein the auxiliary wire includes:
a first end close to the specific point; and
a second end close to the transistor, and
wherein the second end is closer to the second portion than to the first portion.

2. The semiconductor module according to claim 1, wherein the conductive pattern is provided with a slit between the specific point and the first portion.

3. A semiconductor module comprising:
an insulated substrate;
a conductive pattern over the insulated substrate;
a transistor over the conductive pattern; and
a connection terminal over the insulated substrate, the connection terminal being spaced apart from the transistor in a first direction,
wherein the transistor includes:
a first main electrode provided on a first surface facing the conductive pattern;
a second main electrode provided on a second surface opposite to the first surface; and
a control electrode over the second surface, the control electrode being spaced apart from the second main electrode in the first direction,
wherein a current flows from a specific point on the conductive pattern through the transistor to the connection terminal, the specific point being spaced apart from the transistor in the first direction,
wherein the second main electrode includes a first portion and a second portion that is spaced apart from the first portion in a second direction opposite to the first direction, and
wherein the conductive pattern is provided with a slit between the specific point and the first portion.

4. The semiconductor module according to claim 1, further comprising:
a diode over the insulated substrate, the diode being spaced apart from the transistor in the first direction; and
a relay wire electrically connecting the transistor and the diode to each other,
wherein the diode includes:
a cathode electrode provided on a third surface facing the conductive pattern; and
an anode electrode provided on a fourth surface opposite to the third surface,
wherein one end of the relay wire is coupled to the first portion, and
wherein another end of the relay wire is coupled to the cathode electrode.

5. The semiconductor module according to claim 1, further comprising an external connection terminal overlapping the second portion in plan view.
